(19) United States
(12) Patent Application Publication
(10) Pub. No.: US 2025/0102608 A1
(43) Pub. Date: Mar. 27, 2025

(54) Computer-Implemented Method for Ascertaining Correction Information and for Reconstructing Image Data of a Magnetic Resonance Imaging Scan, Processing Device and Computer Program

(71) Applicant: Siemens Healthineers AG, Forchheim (DE)

(72) Inventors: Max Müller, Erlangen (DE); Christian Meixner, Erlangen (DE); Michael Köhler, Nuernberg (DE); Marcel Dominik Nickel, Herzogenaurach (DE); Dominik Paul, Bubenreuth (DE)

(73) Assignee: Siemens Healthineers AG, Forchheim (DE)

(21) Appl. No.: 18/890,999

(22) Filed: Sep. 20, 2024

(30) Foreign Application Priority Data
Sep. 22, 2023 (EP) 23199170.4

(51) Int. Cl. G01R 33/565; G01R 33/483; G06T 11/00

(52) U.S. Cl. CPC G01R 33/56572; G01R 33/4835; G06T 11/006; G06T 2211/412

(57) ABSTRACT

In a method for ascertaining correction information for correcting a magnetic resonance imaging scan, respective first and second magnetic resonance data for at least one gradient direction are acquired, where the first magnetic resonance data is acquired while the magnetic field gradient is applied in the respective gradient direction, and the second magnetic resonance data is acquired while the magnetic field gradient is applied counter to the respective gradient direction. The method may further include determining a respective phase difference for reference points along a respective position space line in the position space that extends in the respective gradient direction based on the first and second magnetic resonance data, and providing the phase differences of at least one subgroup of the reference points as correction information or ascertaining the provided correction information based on the phase differences of at least the subgroup of the reference points.

### CROSS REFERENCE TO RELATED APPLICATIONS

This patent application claims priority to European Patent Application No. 23199170.4, filed Sep. 22, 2023, which is incorporated herein by reference in its entirety.

### BACKGROUND

### Field

The disclosure relates to a computer-implemented method for ascertaining correction information that serves for correcting imaging errors of a magnetic resonance imaging scan and relates to the field inhomogeneities of the magnetic field in an examination volume that result due to the examination volume being exposed to a magnetic field gradient in at least one gradient direction. The disclosure also relates to a computer-implemented method for reconstructing image data of a magnetic resonance imaging scan, to a processing device and to a computer program.

### Related Art

Magnetic resonance imaging has meanwhile become a well-established imaging modality, in particular in the field of medicine. While acquisition trajectories used for Cartesian sampling of the k-space are well-known and routinely employed, non-Cartesian acquisition trajectories have in the meantime also been proposed. For example, radial measurement sequences are used in which individual radial spokes are sampled sequentially in the k-space.

Eddy currents generated by gradient pulses can lead to temporally and spatially variable field perturbations in magnetic resonance devices. In particular in the case of non-Cartesian sampling schemes that use linear acquisition trajectories in different readout directions, in particular, therefore, in a radial sampling of the k-space, the resulting field inhomogeneities can lead to strong artifacts in reconstructed image data, for example to ghosting or to local signal extinctions.

To correct corresponding measurement data, it has been proposed in the prior art to apply a delay time correction (DTC) in which correction data obtained by means of calibration measurements is used in order to shift signal curves that have been acquired for a respective gradient direction in the k-space as a function of the gradient direction. Such a correction is disclosed for example in an article by Tess Armstrong et al. titled “Free-Breathing Liver Fat Quantification Using a Multiecho 3D Stack-of-Radial Technique”, Magn. Reson. Med. 79 (2018), pages 370-382.

However, only gradient-like field perturbations or field perturbations varying at least approximately linearly with the readout direction can be compensated for by a shift in the k-space or the explained delay time correction. On the other hand, field contributions varying non-linearly with the readout direction, for example second-and/or third-and/or higher-order perturbations, can likewise lead to significant image disturbances in some imaging devices or for certain measurement sequences.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows an exemplary embodiment of a processing device according to the disclosure by means of which an exemplary embodiment of an inventive method for ascertaining correction information and for reconstructing image data of a magnetic resonance imaging scan is performed,

FIG. 2 shows a flowchart for the method performed in FIG. 1,

FIG. 3 shows an illustration of the sampling of measurement points in a k-space,

FIG. 4 shows the arrangement of reference points in a position space for which amplitudes and phases of the magnetic resonance signal at the respective reference point can be determined on the basis of the measurement points shown in FIG. 3,

FIG. 5 shows a position space curve which shows the variation of the amplitude of the magnetic resonance signal along one of the position space lines shown in FIG. 4,

FIG. 6 shows phase differences determined in the course of the method shown in FIG. 2, and

FIG. 7 shows an illustration for determining metacorrection parameters in the course of the method shown in FIG. 2.

The exemplary embodiments of the present disclosure will be described with reference to the accompanying drawings. Elements, features and components that are identical, functionally identical and have the same effect are-insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

The object underlying the disclosure is therefore to further improve the detection and in particular the quantification of unwanted field inhomogeneities that result from an application of a gradient to the examination region, in particular due to eddy currents, in order thereby to enable more effective correction of measurement data and consequently further improve image quality.

The object is achieved according to the disclosure by means of a method of the type cited in the introduction, which may comprise the following steps:
acquiring respective first and second magnetic resonance data for at least one gradient direction,
   wherein the first magnetic resonance data is acquired while the magnetic field gradient is applied to the examination volume in the respective gradient direction, and
   wherein the second magnetic resonance data is acquired while the magnetic field gradient is applied to the examination volume counter to the respective gradient direction,
determining a respective phase difference for a plurality of reference points along a respective position space line in the position space, which line extends in the respective gradient direction, on the basis of a difference between
   a determined first phase of the magnetic resonance signal at the respective reference point which is determined on the basis of the first magnetic resonance data, and
   a determined second phase of the magnetic resonance signal at the respective reference point which is determined on the basis of the second magnetic resonance data,
providing the phase differences of at least one subgroup of reference points as correction information or ascertaining the provided correction information as a function of the phase differences of at least the subgroup of reference points.

For a better understanding of the method, it is assumed in the following explanation that the absolute value of the magnetic field gradient in the gradient direction and of the magnetic field gradient counter to the gradient direction is the same. Although this is a particularly advantageous embodiment, such a restriction is not necessarily required, however, and an additional phase difference that would result from the use of different absolute values of the magnetic field gradient can be determined for example analytically and considered. The respective position space line runs in a straight line in the respective gradient direction and may extend as far as the center of the measurement volume or through the center.

Apart from negligible or correctable phase differences in many application cases due to a movement of an examination subject or parts of the examination subject, a non-zero phase difference results substantially entirely from field inhomogeneities that can occur due for example to eddy currents when a gradient is switched. Such field inhomogeneities lead to a change in the local field strength and consequently to a change in the Larmor frequency of the spins, from which a phase offset results over and above the measurement time.

In the case of diametrically opposed magnetic field gradients, it can be assumed that the resulting field inhomogeneities occurring during the acquisition of the first and second magnetic resonance data are likewise at least approximately diametrically opposed also, such that in the method according to the disclosure it is possible to infer directly on the basis of the determined phase difference the strength of the local field inhomogeneity or the deviation from the nominal magnetic field due to eddy currents or other effects.

Additional field inhomogeneities occurring in the case of an active magnetic field gradient due to eddy currents or similar lead in a typical reconstruction to received signals being assigned to the wrong location due to the occurring phase error. As will be explained in detail later with reference to the inventive method for reconstructing image data of a magnetic resonance imaging scan, this can be avoided in that signal curves acquired in the course of the imaging, each of which describes the variation of a k-space amplitude and/or a k-space phase of the magnetic resonance signal along a k-space line in a two-dimensional k-space assigned to a respective measurement slice, are transformed into the position space, rectified there on the basis of the correction information and subsequently back-transformed into the k-space in order to provide corrected signal curves on the basis of which an image reconstruction can then be performed.

If sufficiently small phase differences occur, the difference of the phases or, as will be explained later, the half difference can be used directly as the phase difference. Otherwise, it may be beneficial to avoid phase shifts due to phase overruns by applying a technique known as “phase unwrapping”, as will be explained later.

When diametrically opposed gradients are used for determining the first and second magnetic resonance data, the phase error due to the respective switched gradient corresponds to half of the determined phase difference or the phase difference corrected by means of a “phase unwrapping”, such that this intermediate result can be in particular halved in order to provide the correction information if this is intended to describe the phase error directly at the gradient field strength used in order to ascertain the correction information.

The phase differences may be determined for two gradient directions standing at an angle to one another. In particular, these gradient directions can stand substantially perpendicular to one another, for example at an angle of at least 60° or at least 80°. By acquiring phase differences for a plurality of gradient directions standing at an angle to one another it is possible to estimate, at least approximately, field inhomogeneities due to gradients in arbitrary directions lying within the plane spanned by the two gradient directions and consequently correct them, as will be explained in more detail later with reference to the reconstruction method according to the disclosure.

Instead of using the phase differences directly for correction purposes or as correction information, it may be beneficial firstly to determine correction parameters from these. A predefined correction function can assign a phase difference value to the reference points along the respective position space line as a function of at least one respective correction parameter for the respective gradient direction and of the position of the respective reference point along the respective position space line. The respective correction parameter can then be determined by minimizing a measure for the deviations between the phase difference value specified for the respective reference point by the correction function and the phase difference determined for said reference point, at least for those reference points along the respective position space line that are part of the subgroup, by adjusting the correction parameter. The correction information can then comprise or be dependent on the at least one respective correction parameter for the respective gradient direction.

As a result of using one or more correction parameters as correction information, typical field inhomogeneities can be sufficiently well imaged using just a few correction parameters, for example by means of a polynomial fit. Moreover, this also allows phase difference values to be specified and consequently field inhomogeneities to be estimated for sections of the position space line for which, as will be explained later, no sufficiently low-noise phase information can be acquired in the course of the correction determination in order to determine reliable phase differences there directly. Finally, the use of at least one correction parameter can facilitate the interpolation of correction variables used in the course of the reconstruction of the image data, as will be explained later.

As the correction function, an at least second-or at least third-degree polynomial can be used as a variable in the position of the respective reference point along the respective position space line, wherein at least one of the coefficients of the polynomial is used as a correction parameter. Using a third-degree polynomial is sufficient for the majority of applications. The polynomial does not have to include all powers of the variable in this case. For example, the polynomial may comprise only the first and third power of the variable. In particular at least the coefficient for the third power of the variable, such as the coefficient for all powers of the variable occurring in the polynomial, may be determined as the correction parameter.

The phase differences can be determined for reference points in a plurality of measurement slices succeeding one another in a slice selection direction, wherein a respective pair composed of correction parameter and gradient direction is in each case assigned at least one metacorrection parameter which is provided as part of the correction information or on which the correction information is dependent, wherein a correction value is specified by means of a predefined metacorrection function for the respective pair and the respective measurement slice as a function of the respective metacorrection parameter assigned to the pair and of the position of the respective measurement slice in the slice selection direction. The respective metacorrection parameter can be determined by first determining the at least one respective correction parameter for the respective gradient direction separately for each measurement slice of at least one subgroup of the measurement slices, after which, for the respective pair composed of correction parameter and gradient direction, a measure for the deviations of the correction values specified for said pair for the different measurement slices by means of the metacorrection function is minimized in each case by the respective correction parameter determined for the pair and the respective measurement slice, at least for those measurement slices which are part of the subgroup, by adjustment of the respective metacorrection parameter.

In other words, the metacorrection function is fitted to the variation of the correction values in the slice selection direction by adjustment of the metacorrection parameters, wherein optionally solely the correction values of the measurement slices of the subgroup are considered.

In order to determine the phase differences for a plurality of measurement slices, in the simplest case the measurement slices can be excited separately. In an exemplary embodiment, however, a phase encoding in the slice selection direction is used in the course of the measurement. This is explained in detail later.

Alternatively to determining the metacorrection parameters, the phase differences for reference points in a plurality of measurement slices succeeding one another in the slice selection direction can be determined, wherein the at least one respective correction parameter for the respective gradient direction is first determined separately for each measurement slice of at least one subgroup of the measurement slices, as a result of which a provisional parameter variation of the respective correction parameter is specified in the slice selection direction, after which a smoothing function smooths said provisional parameter variation in order to provide a respective smoothed parameter variation which is provided as part of the correction information or on which the correction information is dependent.

The smoothing of the provisional parameter variation can be achieved for example by means of a fit or a filtering and/or can serve to compensate for the discarding of slices that are not part of the subgroup.

In a further alternative, the phase differences can be determined for reference points in a plurality of measurement slices succeeding one another in the slice selection direction, wherein a predefined correction function assigns a phase difference value to the reference points in a respective plane which is spanned by the respective position space line and the slice selection direction as a function of at least one respective correction parameter for the respective gradient direction and of the position of the respective reference point along the respective position space line and in the slice selection direction, wherein the respective correction parameter is determined by minimizing a measure for the deviations between the phase difference value specified for the respective reference point by the correction function and the phase difference determined for said reference point, at least for those reference points in the respective plane which are part of the subgroup, by adjusting the correction parameter, wherein the correction information may comprise the at least one respective correction parameter for the respective gradient direction or is dependent on said correction parameter.

In this case a two-dimensional fit is therefore performed for the correction function in each case both in the slice selection direction and in the direction of the respective position space line. The subgroup of the considered reference points can in particular comprise exclusively reference points which are part of a measurement slice of the subgroup of the measurement slices. Furthermore, as will be explained later, reference points from regions having a low signal amplitude remain out of consideration.

In addition, the or an amplitude of the magnetic resonance signal at the respective reference point can be determined for the respective reference point on the basis of the first and/or second magnetic resonance data, wherein the subgroup of the slices is selected as a function of the amplitudes of the reference points in the respective measurement slice.

For example, only measurement slices for which the mean value and/or the median of the amplitudes of all reference points in the respective measurement slice or all reference points on the respective position space line in the respective measurement slice reaches or exceeds a respective predefined slice limit value can be accepted into the subgroup.

Alternatively, or additionally, a requirement for including the respective measurement slice in the subgroup can be that the respective amplitude for a specified number or a specified proportion of the reference points reaches or exceeds a predefined amplitude limit value.

Accordingly, for example, those measurement slices can be included in the subgroup for which, on average or for a sufficient number of reference points, a sufficient signal amplitude is present. This is beneficial since at low signal amplitudes the determined phase can have a low signal-to-noise ratio, as a result of which regions of the measurement volume from which low signal strengths are received, for example regions outside of the examination subject, which may remain out of consideration when the correction information is ascertained.

The phase differences can be determined for reference points in a plurality of measurement slices by additional use of a phase encoding in the or a slice selection direction during the acquisition of the respective first and second magnetic resonance data, as a result of which the first and second magnetic resonance data are initially present in the frequency domain in the slice selection direction, after which, by means of a Fourier transform of the respective first and second measurement data in the slice selection direction for different positions in the slice selection direction, and consequently different measurement slices, first partial measurement data dependent on the first measurement data and second partial measurement data dependent on the second measurement data are present in each case for each of the measurement slices, after which the first phases of the magnetic resonance signal are determined for the reference points along the respective position space line in the respective measurement slice on the basis of the respective first partial measurement data and the second phases of the magnetic resonance signal are determined on the basis of the respective second partial measurement data.

By means of this approach, a different correction of the measurement data for different slices can be used with low measurement overhead or generally field inhomogeneities in the slice selection direction can also be considered.

The slice selection direction stands substantially perpendicularly on the at least one gradient direction, for example at an angle of at least 70° or at least 80°.

For the respective reference point, the or an amplitude of the magnetic resonance signal can additionally be determined at the respective reference point on the basis of the first and/or second magnetic resonance data. On the one hand, only reference points for which the amplitude reaches or exceeds an amplitude limit value can be accepted into the subgroup of reference points. On the other hand, in addition or alternatively, during a determination of the phase differences for reference points in a plurality of successive measurement slices in the or a slice selection direction, reference points lying on a respective straight line in the slice selection direction can be exclusively accepted into the subgroup when a common amplitude value determined on the basis of their amplitudes reaches or exceeds a group limit value.

A kind of gating can therefore be performed for the reference points such that, for example, for the above-explained determination of the correction parameter, only reference points having a sufficiently strong magnetic resonance signal are considered. This is beneficial because in reference points where the magnetic resonance signal has a very low amplitude, the determined phase is typically characterized substantially by a noise component of the signal or is at least considerably disturbed thereby. Taking corresponding phases into account could therefore reduce the quality of the correction, though this can be avoided by the selection of the subgroup of reference points.

In particular when an averaging or a fit is to be performed across a plurality of measurement slices, it can be beneficial not to consider regions in which, for example, on average over all the slices only low amplitudes occur. In particular a mean value or a median of the amplitudes of the reference points lying on the respective straight line in the slice selection direction can be determined as a common amplitude value.

In many application cases, it is sufficient to determine the amplitude exclusively on the basis of the first or exclusively on the basis of the second magnetic resonance data. However, it is also possible for example to determine a respective subamplitude on the basis of the first and second magnetic resonance data and to determine the amplitude drawn upon for the limit value comparison for example by averaging the subamplitudes. It would, however, also be possible for example to determine a separate amplitude in each case on the basis of the first and second magnetic resonance data and for example to include only reference points in the subgroup for which both amplitudes exceed the amplitude limit value or similar.

In some cases, it may be advantageous not to include in the subgroup all the reference points whose amplitudes reach or exceed the amplitude or group limit value. If, for example, it is known that sufficient amplitudes are likely only in a central region of the measurement volume, for example because an examination subject positioned there is surrounded by air, it may be beneficial not to accept into the subgroup all the reference points on a respective position space line that are spaced further apart from the center of the examination region than a reference point on said position space line whose amplitude falls below the limit value.

The phase differences for the respective position space line can be determined by means of a phase correction algorithm which is configured to detect and correct phase shifts due to a phase overrun by analysis of the variation of the difference between the determined first and second phase along the respective position space line. Given sufficient field inhomogeneity or gradient strength, phase shifts can occur along the position space line, with the result that, in particular after the subtraction, a phase unwrap or an unwinding of the phase can still be performed. In this process, phase shifts between adjacent reference points along the position space line can be detected which typically result from a phase overrun of the cyclical phase and can be compensated for in a per se known manner for example by adding or subtracting an integral multiple of 360° to phase differences for the reference points on the other side of the phase shift.

An offset of the phase difference resulting from this can subsequently be eliminated for example by setting the phase difference at the central reference point to zero and reducing the further phase differences accordingly by the original value of the phase difference for the central reference point.

The first and second magnetic resonance data can in each case comprise a plurality of partial channel data which is acquired via different measurement channels, received via different measurement coils, for example. In principle, the respective partial channel data can be directly combined in order to provide the first and second magnetic resonance data and process said data as explained above.

However, it may be advantageous initially to process the partial channel data separately from one another. For example, the phase differences and/or the correction parameters and/or the metacorrection parameters can first be determined separately for the different channels and subsequently for example an averaging or a weighted sum can be calculated in order to provide a respective overall result for the respective variable. In this process it is also possible to discard the data from certain channels, for example if a low signal-to-ratio is determined for these and/or if the variables resulting for one channel are not consistent with variables determined for other channels. This can be indicative of a defect of the channel, for example.

In addition to the computer-implemented method for ascertaining correction information, the disclosure relates to a computer-implemented method for reconstructing image data of a magnetic resonance imaging scan in an examination volume, wherein signal curves are processed, each of which describes the variation of a k-space amplitude and/or a k-space phase of the magnetic resonance signal along a k-space line in a two-dimensional k-space assigned to a respective measurement slice, wherein the method may comprise the following steps:
Fourier transform of the respective signal curve in order to provide a respective position space curve,
local stretching and/or compression of the respective position space curve in order to provide a respective corrected position space curve, wherein the local degree of compression and/or stretching is specified as a function of location-dependent correction information relating to field inhomogeneities of the magnetic field in the examination volume which result due to the examination volume being exposed to a magnetic field gradient,
Fourier transform of the respective corrected position space curve in order to provide a respective corrected signal curve, and
reconstruction of the image data on the basis of the corrected signal curves.

As has already been explained above for ascertaining the correction information, field inhomogeneities in the measurement volume lead to a change in the phase of the magnetic resonance signal emitted in the respective region of the examination volume.

If a phase encoding is used in the gradient direction, the field inhomogeneities consequently lead to a local distortion of the position space curve, i.e. the Fourier transform of the signal curve of the received measurement signal. However, since the field inhomogeneities of the magnetic field in the examination volume are known at least approximately owing to the use of the correction information or can be determined at least approximately on the basis of said correction information, the falsification of the signal curve resulting from said distortion can be compensated for at least to a large extent and consequently the quality of the reconstruction result can be significantly improved.

The field inhomogeneity of the magnetic field gradient can be described in particular by the above-explained phase differences for the reference points or by variables determined from said phase differences, i.e. in particular by the at least one above-explained correction parameter or metacorrection parameter for the respective gradient direction. The correction information can therefore comprise these phase differences, correction parameters and/or metacorrection parameters or describe them, for example by specification of parameters for a predefined function.

Correction information that has been ascertained by means of the inventive computer-implemented method for ascertaining correction information may be used as the correction information.

Since the signal curves of the individual k-space lines are Fourier-transformed and corrected separately from one another, the position space curve assigns the result of the Fourier transform, i.e. in particular a position space amplitude and/or phase or quadrature components of the magnetic resonance signal, in each case to coordinates in a one-dimensional position space. A direction in which the respective k-space line extends can be considered in the correction by using partial information of the correction information or correction variables determined from the correction information for correcting the respective signal curve or position space curve which are assigned to the gradient direction used during the acquisition of said signal curve or to the direction of the k-space line.

The k-space line may run rectilinearly and may comprise in particular the k-space center. In this case, in particular an at least approximately constant magnetic field gradient can be applied to the examination volume during the acquisition of the signal curve such that a phase encoding in the line direction is performed.

The signal curves are based in particular on a radial sequence with phase encoding in the radial direction. The magnetic field gradients switched during the acquisition of different signal curves for different k-space lines standing at an angle to one another can be in particular equal in absolute value and differ from one another only in respect of their gradient direction. This is advantageous in particular when it is aimed to correct field inhomogeneities whose strength is not linearly dependent on the strength of the switched magnetic field gradients. If, for example, the above-explained ascertainment of the correction information is used, very good correction results are achieved already in this case when phase differences for two gradient directions standing at an angle to one another are recorded. The at least approximately the same gradient field strength may be used in this case as is used in the course of the acquisition of the signal curves.

The acquisition of the signal curves can be performed as part of the method or also be completed prior to the commencement of the method.

The ascertaining of the correction information can be a part of the computer-implemented method for reconstructing the image data of the magnetic resonance imaging scan or can have been completed already before the commencement of the method. In an exemplary embodiment, the respective first and second magnetic resonance data used for ascertaining the correction information can be acquired in the course of the magnetic resonance imaging procedure or immediately before or after the same or at least by means of the same imaging device without relocating the examination subject. By this means it can be ensured on the one hand that sufficient signal amplitudes are present in the course of ascertaining the correction information for regions of the measurement volume in which the examination subject is imaged. Furthermore, this also potentially enables field inhomogeneities resulting from the interaction of the examination subject with the imaging device to be detected and corrected.

The correction information can specify first correction variables for a first k-space direction and second correction variables for a second k-space direction standing at an angle with respect to the first k-space direction, wherein the local degree of compression and/or stretching used in the course of determining the corrected signal curve for at least one of the k-space lines extending at an angle to the first and second k-space direction is determined as a function of interpolated correction variables, each of which is determined as a weighted sum of one of the first and one of the second correction variables.

In particular, the respective k-space line having the first k-space direction can include an offset angle and the weighting of the respective first and second correction variable in the weighted sum can be dependent on the offset angle. In particular, the respective first correction variable can be scaled with the square of the cosine of the offset angle and the respective second correction variable with the square of the sine of the offset angle.

The first and second correction variables added in the weighted sum can be determined in particular in the same way in each case apart from the gradient directions different from one another used in the course of the determination. If, for example, the correction variables relate to phase differences, the phase differences for the respective same position along the respective line in position space can be added in weighted form. If, on the other hand, the correction variables relate for example to correction parameters or metacorrection parameters which are coefficients of a polynomial, the coefficients can be added weighted for the same power of the variable.

The correction variables may be specified for at least approximately orthogonal k-space directions. The k-space directions can correspond to the gradient directions for which, as explained above, phase differences are determined. The k-space directions for which correction variables are specified by means of the correction information can have been specified by means of the geometry of the measurement device, i.e. for example may correspond to the directions of the gradient application by means of a respective pair of gradient coils.

The corrected signal curve for the respective k-space line extending in the first or second k-space direction can be determined directly as a function of the first or second correction variables.

The described procedure enables the correction information to be ascertained with low overhead or very quickly such that it is possible for example to ascertain the correction information immediately before or after acquisition of the signal curves for the imaging without this leading to a noticeable lengthening of the requisite measurement time.

It is also possible in principle that respective correction variables for more than two k-space directions are specified by means of the correction information. In this case an interpolation for k-space lines for which the correction variables are not specified directly can be realized by interpolation between the respective nearest k-space directions.

The correction variables can be specified by means of the correction information directly or also implicitly, for example by specification of parameters of a determination function.

In the method according to the disclosure, image data for a plurality of measurement slices can be reconstructed, wherein measurement data is processed during the acquisition of which a phase encoding in a slice selection direction is used in addition, as a result of which the measurement data is present in the frequency domain in the slice selection direction, after which the signal curves are provided by means of a Fourier transform of the respective measurement data in the slice selection direction for different positions in the slice selection direction and consequently for different measurement slices.

Accordingly, in a three-dimensional measurement data acquisition which uses a phase encoding in the slice selection direction, the measurement data may be transformed initially into separate two-dimensional k-spaces, in which the correction can be performed separately in each case. In the simplest case it can be assumed in this process that field inhomogeneities caused as a result of a gradient being applied are the same in all slices, whereby all slices can be corrected in the same way, for example using the same correction variables.

As has already been explained in detail above, however, in the course of ascertaining the correction information, it can also be detected if different field inhomogeneities result in different slices from the gradient application, in particular in that the phase differences are determined separately for the different measurement slices. In this case the correction information can specify separate sets of correction variables for the different measurement slices or corresponding correction variables can be determined for the individual slices on the basis of the correction information, for example on the basis of the above-explained metacorrection parameters.

In addition to the methods according to the disclosure, the disclosure relates to a processing device which is configured for performing the inventive computer-implemented method for ascertaining correction information and/or the inventive computer-implemented method for reconstructing image data of a magnetic resonance imaging scan in an examination volume.

The disclosure also relates to a computer program comprising program instructions which are embodied to implement the inventive computer-implemented method for ascertaining correction information and/or the inventive computer-implemented method for reconstructing image data of a magnetic resonance imaging scan in an examination volume when they are executed on a data processing device.

The disclosure further relates to a data medium comprising the computer program according to the disclosure.

Further advantages and details of the disclosure will become apparent from the following exemplary embodiments as well as from the associated schematic drawings, in which:

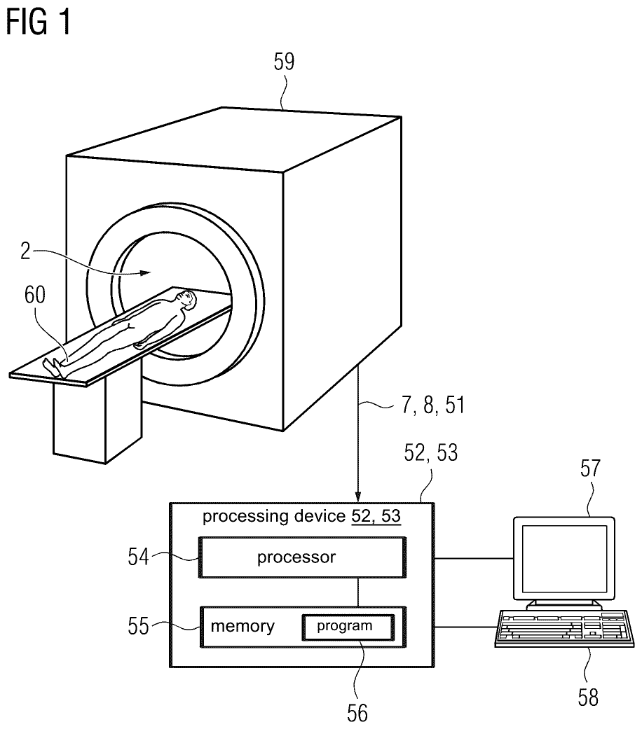

FIG. 1 shows a processing device 52 which serves for reconstructing image data of a magnetic resonance imaging scan. In the example, the measurement data 51 or magnetic resonance data 7,8 processed for this purpose, on the basis of which a correction of the measurement data 51 is carried out in the course of the reconstruction, is provided directly by an imaging device (scanner) 59 into whose examination volume 2 a patient or an examination subject 60 has been received. The processing device 52 may be configured to control one or more operations and/or functions of the imaging device 59, and may be referred to as a controller. The control of the imaging device 59 may be based on one or more user inputs via the input interface 58. In an exemplary embodiment, the processing device 52 includes processing circuitry that is configured to perform one or more operations and/or functions of the processing device 52.

Additionally, or alternatively, one or more components of the processing device 52 includes processing circuitry that is configured to perform operation(s) and/or function(s) of the component(s).

As will be explained in detail later, by the correction of the measurement data 51 it is aimed to correct for artifacts or imaging errors resulting from the fact that when a magnetic field gradient is applied to the examination volume 2, unwanted field inhomogeneities, due for example to eddy currents, can occur which interfere with the imaging.

For this reason, as will be explained in more detail later, certain magnetic resonance data 7,8 is acquired, on the basis of which correction information is ascertained on the basis of which the perturbations of the imaging resulting from such field inhomogeneities can be eliminated or at least largely suppressed. In the example, the imaging can be controlled via an input interface 58 (e.g., keyboard, mouse, touchscreen, etc.) and measurement results or reconstructed image data can be output via a display device 57.

The magnetic resonance data 7,8 and the measurement data 51 can be acquired in the course of a common acquisition process. Alternatively, it would also be possible to read out the magnetic resonance data 7,8 and/or the measurement data 51 from a database for example or solely to ascertain correction information for the subsequent correction of measurement data or solely to acquire the measurement data 51 and use correction information already ascertained previously for its correction.

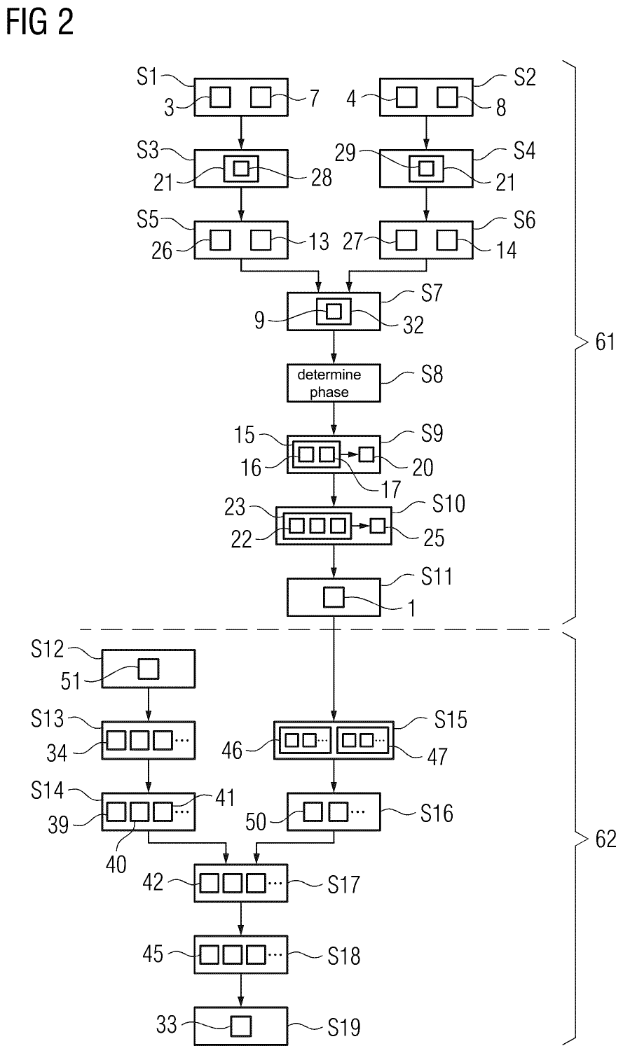

FIG. 2 shows a flowchart for an exemplary embodiment of the method performed by the processing device 52 for ascertaining correction information and for reconstructing image data of a magnetic resonance imaging procedure. The method illustrated in FIG. 2 may comprise a first submethod 61 in which the correction information 1 is ascertained and a second submethod 62 in which the correction information 1 is used in order to correct measurement data 51 of the magnetic resonance imaging procedure in the course of the reconstruction of the image data 33.

The submethods 61, 62 can in principle also be performed spaced apart from one another in time. If it can be assumed for example that the effect of the examination subject 60 on field inhomogeneities resulting from the application of field gradients 7, 8 in the examination volume 2 can approximately be neglected, then the correction information 1 can be ascertained jointly for example for a plurality of imaging procedures on different examination subjects 60, for example at the time of production or calibration of the imaging device 59.

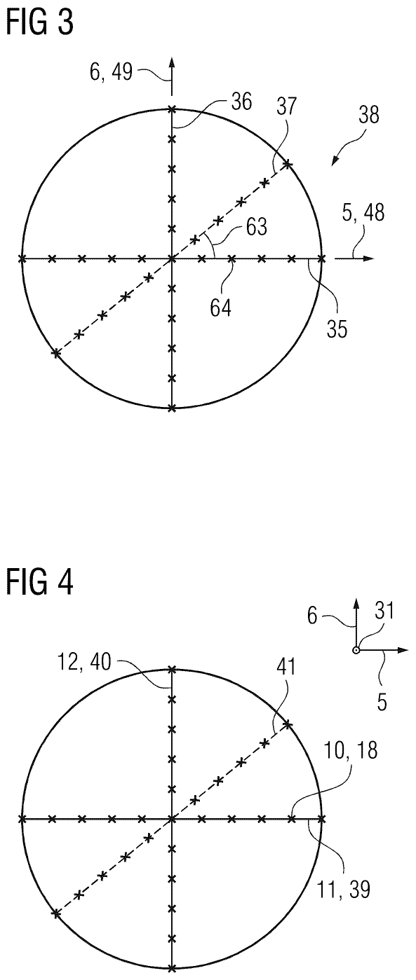

However, as it is typically sufficient to acquire magnetic resonance data 7, 8 for just two gradient directions 5, 6, which are represented schematically in FIGS. 3 and 4, in the course of the submethod 61, the measurement time required for the first submethod 61 is typically negligible compared with the measurement time for the imaging itself, such that the first submethod 61 may be performed in addition to any acquisition of measurement data 51 for imaging or at least once in the course of an imaging series conducted on the same examination subject 60.

FIG. 2 shows an advantageous embodiment of the overall method. As has already been presented in the general part of the description, it is not necessary for the implementation of the subject matter of the disclosure for all the method steps shown or explained to be performed or for all the explained features to be implemented. Also, some of the explained embodiments can be replaced by alternative embodiments. While attention is focused in the following explanation on individual exemplary modification options of the explained method, other variations are also possible above and beyond these, in particular modifications which have already been discussed in the general part of the description.

Submethod 61 is a method for ascertaining correction information 1. The correction information 1 serves for correcting imaging errors of a magnetic resonance imaging scan and relates to field inhomogeneities of the magnetic field in the examination volume 2, which field inhomogeneities result due to a magnetic field gradient 3, 4 being applied to the examination volume 2 in at least one gradient direction 5, 6.

In the example, correction information is ascertained in this process for the two gradient directions 7, 8. However, since the method steps S1 to S10 performed for the respective gradient direction 5, 6 are identical apart from the direction of the field application, these steps are described only for the gradient direction 5 and for clarity of illustration reasons are also shown only for this gradient direction 5 in FIG. 2. The same steps are performed correspondingly for the gradient direction 6.

In step S1, first magnetic resonance data 7 is acquired while the examination volume 2 is exposed to the magnetic field gradient 3 in the gradient direction 5. This produces a phase encoding in the gradient direction 5.

If an acquisition of the magnetic resonance data 7 for a single excited measurement slice is initially assumed for simplicity, the magnetic field gradient would trigger a sampling of the two-dimensional k-space 38 shown schematically in FIG. 3 in the gradient direction 5 and consequently along the k-space line 35. Accordingly, measurement values are acquired successively for the k-space points 64 along the k-space line 35. For clarity of illustration reasons, only ten k-space points 64 are shown in this case, wherein typically a higher-density data acquisition is performed.

In the course of the measurement data acquisition, quadrature components of the receive signal are acquired, with the result that the k-space amplitudes and k-space phases of the magnetic resonance signal are known for the different k-space points on the basis of said quadrature components.

In step S2, second magnetic resonance data 7 is acquired while the examination volume 2 is exposed to the magnetic field gradient 4 counter to the gradient direction 5. Apart from the different gradient sign, step S2 corresponds to the previously explained step S1.

In order to obtain additional information in relation to the field inhomogeneity in the slice selection direction 31, which stands in particular perpendicularly on the k-space plane shown in FIG. 3 or the position space plane shown in FIG. 4, a phase encoding in the slice selection direction 31 is additionally performed in the example in steps S1 and S2 during the acquisition of the respective magnetic resonance data 7, 8. As a result of this, the first and second magnetic resonance data 7, 8 are initially present in frequency-encoded form in the slice selection direction 31.

In steps S3 and S4, a Fourier transform of the respective first or second measurement data 7, 8 is then performed in each case in the slice selection direction 31. By this means, first partial measurement data 28 dependent on the first measurement data 7 and second partial measurement data 29 dependent on the second measurement data 8 are generated for each of the measurement slices 21 in each case for different positions 24 in the slice selection direction 31 and consequently for different measurement slices 21. The partial measurement data 28 and 29 thus relate to k-space amplitudes and k-space phases of the magnetic resonance signal along the k-space lines 35, 36, which are frequency-encoded in the respective gradient direction 5, 6. The following steps S5 to S7 can then be performed separately for the individual slices 21.

In step S5, a Fourier transform of the partial measurement data 28 can therefore be performed in the position space for reference points 10 along a respective position space line 11, 12 which runs parallel to the respective gradient direction 5, 6 in order to determine in each case a phase 13 and an amplitude 26 of the magnetic resonance signal for the respective position in the position space. For clarity of illustration reasons, only ten reference points 10 are used in the example. In real-world applications, considerably more reference points, for example over one hundred reference points, may be used. An example of a position space curve 41 which can result for the amplitude 26 along one of the position space lines 11,12 is shown in FIG. 5.

In step S6, a phase 14 and an amplitude 27 of the magnetic resonance signal at the respective position in the position space are determined in the same way in each case for the reference points 10 along the respective position space line 11, 12 in the position space.

If the first and second measurement data 7, 8 are acquired within a sufficiently short time window so that movements of the examination subject 60 in the examination volume 2 can be at least approximately neglected, then it would initially be assumed that, apart from a noise contribution, the two amplitudes 26, 27 and phases 13, 14 determined for the respective reference points 10 are in each case identical to one another. As has already been discussed in detail in the general part, however, exposure of the examination volume 2 to a field in the respective gradient direction 5, 6 and counter to the respective gradient direction typically leads to field inhomogeneities, for example due to induced eddy currents, wherein at least approximately equal absolute values of the local field inhomogeneity and different polarities of the local field inhomogeneity result for the two different directions of the sampling of the k-space for a respective position in the examination volume 2. The determined phases 13, 14 can therefore be used in order to quantify the local field inhomogeneity at the respective reference point or its effect on the imaging.

In step S7, a phase difference 9 is first determined for this purpose for the respective reference point 10. Since the phase of the magnetic resonance signal is a cyclic variable, phase shifts are detected and corrected in this process by means of a phase unwrap. The phase differences 9 for the respective position space line are therefore determined by means of a phase correction algorithm 32 which is configured to detect and correct phase shifts due to a phase overrun by analyzing the variation of the difference between the determined first and second phase 13, 14 along the respective position space line 11, 12.

Corresponding phase correction algorithms 32 are already used for a wide variety of purposes in the context of magnetic resonance imaging and shall therefore not be explained in detail. An offset caused by the phase correction algorithm 32 can be corrected by reducing the result of the phase correction algorithm 32 for all reference points 10 by the phase difference determined following application of the phase correction algorithm 32 for the reference point 10 lying centrally on the respective position space line 11, 12.

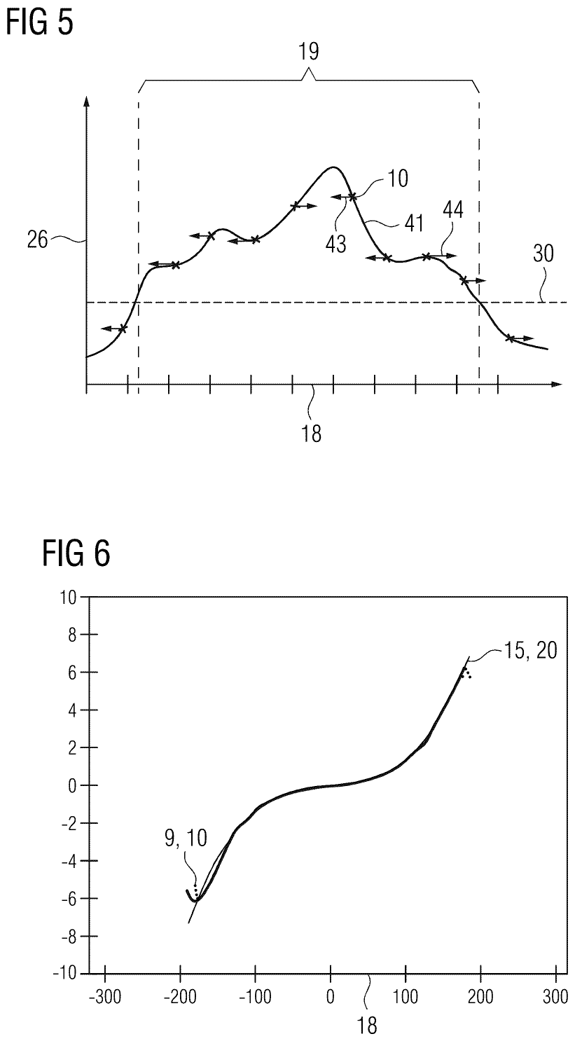

FIG. 6 shows an example in which the phase differences 9 for a plurality of reference points 10 or positions 18 along one of the position space lines 11, 12 are illustrated. In order to represent the variation of the phase difference 10 along the position space line 11, 12 more clearly, considerably more reference points 10 are used in this example than are shown in FIGS. 4 and 5.

The resulting phase difference is at least approximately equivalent to double the phase difference resulting at the respective reference point 10 due to the respective switched magnetic field gradient 3, 4 because, as explained above, a field application in opposite directions leads to an opposite sign of the resulting field inhomogeneity, with which absolute values of the resulting phase errors are added in the subtraction of the phases 13, 14.

As already discussed in the general part, the phase differences for the individual reference points 7 can in principle be used directly as correction information 1. However, a further improvement in the correction that is explained later can be achieved by means of the further steps explained in the following.

In steps S8 to S10, correction parameters 16, 17 and, on the basis of these, metacorrection parameters 22 are determined which, by means of a parameterization of the metacorrection function 23 or the correction function 15, at least approximately describe the variation of the phase differences 9 in the examination volume 2 and consequently the field inhomogeneities. Such a description is in particular advantageous because by this means it is also possible to describe phase differences 9 or field inhomogeneities in regions of the measurement volume 2 in which, due to a very low amplitude of the magnetic resonance signal 2, for example because said regions lie outside of the examination subject 60, the determined phases 13, 14 are severely corrupted by noise and consequently the initially determined phase differences are likely to be seriously subject to error.

To achieve this, in step S8, a subgroup of the measurement slices 21 and a subgroup 19 of the reference points 10 in these slices 21 are initially chosen in or at which the magnetic resonance signal has a sufficient amplitude 13 or 14 in order to enable a robust phase determination.

It can be assumed approximately that the amplitudes 13, 14 are identical to one another and the selection can be based exclusively on the basis of one of these two amplitudes 13, 14. In the example, for conciseness of illustration reasons, the subgroups of the reference points 10 and slices 21 are selected solely as a function of the amplitudes 13.

Alternatively, however, such an evaluation can be carried out both for the amplitude 13 and for the amplitude 14, and only slices 21 and reference points 10 chosen on the basis of both amplitudes 13, 14 can be included in the respective subgroup. Alternatively, it would also be possible, for example, to conduct the evaluation on the basis of a sum or a mean value of the amplitudes 13, 14.

Firstly, it is aimed to choose a subgroup of the slices 21 within which sufficient amplitudes 13 occur. To that end, in the example, for each of the slices 21, the amplitudes of the reference points 10 lying in the respective measurement slice are added and this sum is compared with a limit value. In the example, the subgroup of the slices 21 may comprise only those slices 21 for which this sum reaches or exceeds a predefined limit value. This means that in particular slices 21 lying outside of the examination subject 60 or in which predominantly air and/or other materials having a low magnetic resonance signal are imaged can remain out of consideration.

The subgroup 19 of the reference points 10 can in particular be selected solely from the reference points 10 lying within slices 21 in the subgroup of the slices 21. Also, in the example, only reference points 10 are included in the subgroup 19 of the reference points 10 for which the amplitude 13 there exceeds an amplitude limit value 30. Such a selection is illustrated by way of example in FIG. 5, which shows a position space curve 41 of the amplitude 26.

If it is assumed that only a single examination subject 60 is imaged, the subgroup 19 of the reference points 10 can furthermore include only reference points 10 lying in a cohesive region of the measurement slice 21, within which the amplitude 13 of all the reference points 10 reaches or exceeds the amplitude limit value 30.

In step S9, correction parameters 16, 17 are determined by fitting a correction function 15 by suitable choice in each case of the correction parameters 16, 17 to the phase differences 9 that were determined for the different reference points 10 or positions 18 along the respective position space line 11, 12 for the respective measurement slice 21, wherein, in the example, only the reference points 10 that are part of the subgroup 19 are considered. In other words, a measure for the deviations between the phase difference value 20 predefined for the respective reference point 10 by the correction function 15 and the phase difference 9 determined for said reference point 10 is minimized for those reference points 10 along the respective position space line 11, 12 that are part of the subgroup 19 by adjusting the correction parameter 16, 17.

An example of such a fitted correction function 15 or the phase values 20 predefined by it is shown in FIG. 6. In this case, as the correction function 15 in the example, a third-degree polynomial is used as a variable in the position 18 of the respective reference point 10 along the respective position space line 11, 12, wherein the correction parameters 16, 17 are the coefficients of the polynomial for the first and third power of the variable.

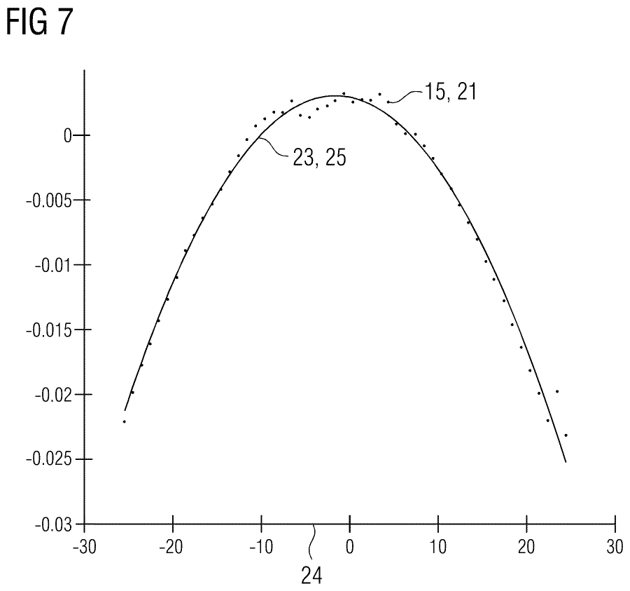

As shown schematically in FIG. 7, next, in step S10, metacorrection parameters 22 are determined for a respective pair composed of a respective correction parameter of the correction parameters 16, 17 and a respective gradient direction 5, 6 by fitting a metacorrection function 23 parameterized by means of the metacorrection parameters 22 to the variation of the respective correction parameter 16, 17 for the respective gradient direction 5, 6 in the slice selection direction 24. In the example, only the measurement slices in the subgroup of measurement slices are taken into consideration in this case. In other words, for the respective pair, a measure for the deviations of the correction values 25 predefined for the different measurement slices 21 by the metacorrection function 23 for said pair by the respective correction parameter 16, 17 determined for the pair and the respective measurement slice 21 is minimized in each case for those measurement slices 21 that are part of the subgroup of measurement slices by adjusting the metacorrection parameters 22.

The metacorrection parameters 22 can then be provided as correction information 1.

As has already been explained in the general part, a smoothing of the correction parameters 16, 17 in the slice selection direction 31, for example by means of a filtering, can also be performed instead of determining the metacorrection parameters 22. In a further alternative explained in greater detail in the general part, it would be possible, instead of the separate fit operations in steps S9 and S10, to fit a correction function that is dependent on the position of the respective reference point along the respective position space line 11, 12 and in the slice selection direction 31 directly to the determined phase differences in a plane spanned by the respective position space line 11, 12 and the slice selection direction 31.

With step S12 there begins the second submethod 62, which is a method for reconstructing image data 33 of a magnetic resonance imaging scan in the examination volume 2, in which the correction information 1 is used for correcting imaging errors that result from unwanted field inhomogeneities of the magnetic field in the examination volume 2, due to eddy currents, for example.

In this case, in step S12, measurement data 51 is first acquired which, in the example, is captured by means of a radial sequence in which the k-space is sampled in a star shape perpendicularly to the slice selection direction 31, i.e. in a k-space plane shown in FIG. 4. During the acquisition of the measurement data for a respective k-space direction or k-space line 35, 36, 37, a field gradient is therefore switched in the respective gradient direction 5, 6. In this process, a separate gradient coil pair can be provided in each case for the gradient directions 5, 6 and, for the sampling of k-space lines 37 standing at an angle to the k-space lines 35, 36, gradients can be superimposed in the gradient directions 5,6 in order to provide overall a total gradient standing at an angle to the gradient directions 5, 6. For clarity of illustration reasons, only three k-space lines 35, 36,37 are depicted in FIG. 3. Typically, however, a plurality of k-space lines are sampled in order to realize a high-density sampling of the k-space.

In the example, a phase encoding in the slice selection direction 31 is used in addition during the acquisition of the measurement data 51. Accordingly, the measurement data is initially present in a three-dimensional k-space or, viewed in the slice selection direction 31, in the frequency domain.

The measurement data assigned to a respective k-space line 35, 36, 37 is subsequently Fourier-transformed in step S13 in order to determine, for individual measurement slices 21 succeeding one another in the slice selection direction 31, a respective signal curve 34 for the respective k-space line 35, 36, 37 in the respective measurement slice 21, each of which describes the variation of a k-space amplitude and/or a k-space phase of the magnetic resonance signal along the k-space line 35, 36, 37.

In step S14, a Fourier transform of the respective signal curve 34 is then performed in order to provide a respective position space curve 39, 40, 41. The respective position space curve 39, 40, 41 describes the amplitude 26 or phase 13 of the magnetic resonance signal for the different positions along the respective position space curve 39, 40, 41. A position space curve 41 for the amplitude 26 is shown by way of example in FIG. 5.

The different position space curves 35, 36, 37 are to be distorted as a function of the correction information 1 in order to compensate for imaging errors due to field inhomogeneities. To that end, in step S15 in the example, first correction variables 46 are initially determined for the first k-space direction 48 and second correction variables 47 for the second k-space direction 49 for the respective measurement slice 21. Since the correction information 1 in the example specifies the metacorrection parameters 22, the metacorrection function 23 can be used, as explained above, in order to specify a correction parameter value 25 for the respective measurement slice 21, the respective correction parameter 16, 17 and the respective k-space direction.

In step S16, interpolated correction variables 50 are additionally determined for k-space lines extending at an angle to the first and second k-space direction 48, 49, for the k-space line 37, for example. For this purpose, an interpolation in the circumferential direction can be performed in FIG. 4. In particular, the interpolated correction variable 50 can be calculated for the respective correction parameter 16, 17 as a weighted sum of the correction parameters for the gradient directions 5, 6 on the same radius, wherein specifically the respective correction variable for the gradient direction 5 can be scaled with the square of the cosine of the offset angle 63 and the respective correction variable for the gradient direction 6 with the square of the sine of the offset angle 63.

In step S17, the respective position space curve 39, 40, 41 is locally stretched and/or compressed in order to provide a respective corrected position space curve 42, as is illustrated schematically in FIG. 5 by means of arrows that represent the shifting of defined reference points. The local degree of the compression 43 and/or stretching 44 is determined as a function of the correction information 1, namely, in the example, actually as a function of the correction variables 46, 47 or of the interpolated correction variables 50 for the k-space line 35, 36, 37 assigned to the respective position space curve 39, 40, 41.

Since, in the example, the correction variables 46, 47, 50 in each case specify values for the correction parameters 16, 17 of the correction function 15, the phase difference values 20 can be determined, as explained above, for any reference points or positions 18 along the respective position space curve 39, 40, 41.

Since the phase difference values 20 at least approximately describe the phase differences 9 that were determined in the course of ascertaining the correction information and that correlate with the degree of the field inhomogeneity at the respective position space position, it can be ascertained directly from the determined phase difference value 20 for the respective position 18 for the respective reference point 10 in which direction and how strongly the respective reference point 10 should be shifted for the correction. A corresponding relationship can be specified for example by means of a look-up table or a scaling factor. These shifts of the reference points 10 can be realized by suitable local compression and/or stretching of the position space curve and as a result the corrected position space curve 25 can be provided.

In step S18, a Fourier transform of the respective corrected position space curve 42 can then be performed in order to provide a respective corrected signal curve 45, on the basis of which, in step S19, a reconstruction of the image data 33 can then be carried out in the customary manner.

In the example, the shown submethods are implemented by means of a processing device 52, as depicted in FIG. 1. In the example, this is formed by a data processing device 53 which may comprise a processor 54 and a memory 55 in which a computer program 56 implementing the submethods 61, 62 or at least one of the submethods is stored.

The processing device 52 in the example is represented as a separate component, but it is also possible to integrate the processing device 52 into the imaging device 59 or into a workstation computer which serves for processing the measurement data 51, or for example to use a server or a cloud solution as the processing device.

Although the disclosure has been illustrated and described in more detail on the basis of the exemplary embodiment(s), the disclosure is not limited by the disclosed examples and other variations can be derived herefrom by the person skilled in the art without leaving the scope of protection of the disclosure.

Independent of the grammatical term usage, individuals with male, female or other gender identities are included within the term.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A computer-implemented method for ascertaining correction information usable to correct imaging errors of a magnetic resonance imaging scan and relating to field inhomogeneities of a magnetic field in an examination volume resulting from a magnetic field gradient being applied to the examination volume in at least one gradient direction, the method comprising:
acquiring respective first and second magnetic resonance data for the at least one gradient direction, wherein:
the first magnetic resonance data is acquired while the magnetic field gradient is applied to the examination volume in the respective gradient direction, and
the second magnetic resonance data is acquired while the magnetic field gradient is applied to the examination volume counter to the respective gradient direction;
determining a respective phase difference for a plurality of reference points along a respective position space line in the position space extending in the respective gradient direction, wherein the respective phase difference is determined based on a difference between:
a determined first phase of the magnetic resonance signal at the respective reference point determined based on the the first magnetic resonance data, and
a determined second phase of the magnetic resonance signal at the respective reference point determined based on the the second magnetic resonance data; and
providing the phase differences of at least one subgroup of the reference points as correction information or determining the provided correction information as a function of the phase differences of at least the subgroup of the reference points.

2. The computer-implemented method as claimed in claim 1, wherein:
a predefined correction function is configured to assign a phase difference value to the reference points along the respective position space line based on at least one respective correction parameter for the respective gradient direction and the position of the respective reference point along the respective position space line;
the at least one respective correction parameter is determined by minimizing a measure for deviations between the phase difference value specified by the correction function for the respective reference point and the phase difference determined for the respective reference point, at least for those reference points along the respective position space line that are part of the subgroup, by adjusting the correction parameter; and
the correction information comprises or is dependent on the at least one respective correction parameter for the respective gradient direction.

3. The computer-implemented method as claimed in claim 2, wherein, as the correction function, an at least second-or at least third-degree polynomial is used as a variable in a position of the respective reference point along the respective position space line, at least one of the coefficients of the polynomial being used as a correction parameter.

4. The computer-implemented method as claimed in claim 2, wherein:
the phase differences for reference points in a plurality of measurement slices succeeding one another in a slice selection direction are determined;
a respective pair composed of correction parameter and gradient direction is in each case assigned at least one metacorrection parameter which is provided as part of the correction information or on which the correction information is dependent;
a correction value is specified using a predefined metacorrection function for the respective pair and the respective measurement slice based on the respective metacorrection parameter assigned to the pair and the position of the respective measurement slice in the slice selection direction; and
the respective metacorrection parameter is determined by:
determining the at least one respective correction parameter for the respective gradient direction separately for each measurement slice of at least one subgroup of the measurement slices, and
for the respective pair of correction parameter and gradient direction, minimizing a measure for the deviations of the correction values specified for said pair for the different measurement slices using the metacorrection function in each case by the respective correction parameter determined for the pair and the respective measurement slice, at least for those measurement slices which are part of the subgroup, by adjustment of the respective metacorrection parameter.

5. The computer-implemented method as claimed in claim 2, wherein:
the phase differences are determined for reference points in a plurality of measurement slices succeeding one another in a slice selection direction; and
the at least one respective correction parameter for the respective gradient direction is determined separately for each measurement slice of at least one subgroup of the measurement slices, as a result of which a provisional parameter variation of the respective correction parameter is specified in the slice selection direction, after which a smoothing function smooths the provisional parameter variation to provide a respective smoothed parameter variation which is provided as part of the correction information or on which the correction information is dependent.

6. The computer-implemented method as claimed in claim 1, wherein:
the phase differences are determined for reference points in a plurality of measurement slices succeeding one another in a slice selection direction,
a predefined correction function assigns a phase difference value to the reference points in a respective plane which is spanned by the respective position space line and the slice selection direction as a function of at least one respective correction parameter for the respective gradient direction and of the position of the respective reference point along the respective position space line and in the slice selection direction;
the respective correction parameter is determined by minimizing a measure for the deviations between the phase difference value specified for the respective reference point by the correction function and the phase difference determined for the respective reference point, at least for those reference points in the respective plane which are part of the subgroup, by adjusting the correction parameter; and,
the correction information comprises or is dependent on the at least one respective correction parameter for the respective gradient direction.

7. The computer-implemented method as claimed in claim 4, wherein an amplitude of the magnetic resonance signal at the respective reference point is determined for the respective reference point based on the first and/or second magnetic resonance data, the subgroup of the slices being selected based on the amplitudes of the reference points in the respective measurement slice.

8. The computer-implemented method as claimed in claim 1, wherein the phase differences are determined for reference points in a plurality of measurement slices based on a phase encoding in a slice selection direction during the acquisition of the respective first and second magnetic resonance data, as a result of which the first and second magnetic resonance data are initially present in a frequency domain in the slice selection direction, after which, by a Fourier transform of the respective first and second measurement data in the slice selection direction for different positions in the slice selection direction and consequently different measurement slices, first partial measurement data dependent on the first measurement data and second partial measurement data dependent on the second measurement data are present in each case for each of the measurement slices, after which, for the reference points along the respective position space line in the respective measurement slice, the first phases of the magnetic resonance signal are determined based on the respective first partial measurement data, and the second phases of the magnetic resonance signal are determined based on the respective second partial measurement data.

9. The computer-implemented method as claimed in claim 1:
wherein an amplitude of the magnetic resonance signal at the respective reference point is determined for the respective reference point based on the first and/or second magnetic resonance data; and
wherein:
only reference points are included in the subgroup of reference points for which the amplitude reaches or exceeds an amplitude limit value; and/or
during a determination of the phase differences for reference points in a plurality of measurement slices succeeding one another in a slice selection direction, reference points that lie on a respective straight line in the slice selection direction are accepted into the subgroup only when a common amplitude value determined based on their amplitudes reaching or exceeding a group limit value.

10. The computer-implemented method as claimed in claim 1, wherein the phase differences for the respective position space line are determined using a phase correction algorithm configured to detect and correct phase shifts due to a phase overrun by analysis of the variation of the difference between the determined first and second phase along the respective position space line.

11. A non-transitory computer-readable storage medium with an executable program stored thereon, wherein, when executed, the program instructs a processor to perform the method of claim 1.

12. An apparatus comprising:
one or more processors; and
memory storing instructions that, when executed by the one or more processors, cause the apparatus to perform the method of claim 1.

13. A computer-implemented method for reconstructing image data of a magnetic resonance imaging scan in an examination volume, the method comprising:
processing signal curves, each of which describes variation of a k-space amplitude and/or a k-space phase of a magnetic resonance signal along a k-space line in a two-dimensional k-space assigned to a respective measurement slice;
performing a Fourier transform of the respective signal curve to provide a respective position space curve;
performing local stretching and/or compression of the respective position space curve to provide a respective corrected position space curve, wherein a local degree of compression and/or stretching is specified as a function of location-dependent correction information relating to field inhomogeneities of the magnetic field in the examination volume which result due to a magnetic field gradient being applied to the examination volume;
performing a Fourier transform of the respective corrected position space curve to provide a respective corrected signal curve; and
reconstructing the image data based on the corrected signal curves.

14. The computer-implemented method as claimed in claim 13, wherein:
the correction information specifies first correction variables for a first k-space direction and second correction variables for a second k-space direction standing at an angle to the first k-space direction; and
the local degree of compression and/or stretching used in determining the corrected signal curve for at least one of the k-space lines extending at an angle to the first and second k-space direction is determined based on interpolated correction variables, each of which is determined as a weighted sum of one of the first and one of the second correction variables.

15. The computer-implemented method as claimed in claim 13, wherein:
image data for a plurality of measurement slices is reconstructed, measurement data being processed during the acquisition of which a phase encoding in a slice selection direction is used, as a result of which the measurement data is present in the frequency domain in the slice selection direction; and
after which the signal curves are provided by a Fourier transform of the respective measurement data in the slice selection direction for different positions in the slice selection direction and consequently for different measurement slices.

16. A non-transitory computer-readable storage medium with an executable program stored thereon, wherein, when executed, the program instructs a processor to perform the method of claim 13.

17. An apparatus comprising:
one or more processors; and
memory storing instructions that, when executed by the one or more processors, cause the apparatus to perform the method of claim 13.
